(19) United States
(12) Patent Application Publication
(10) Pub. No.: US 2013/0240008 A1
(43) Pub. Date: Sep. 19, 2013

(54) SYSTEM AND METHOD FOR MOUNTING PHOTOVOLTAIC MODULES

(71) Applicant: Christopher Baker, Muamee, OH (US)

(72) Inventor: Christopher Baker, Muamee, OH (US)

(21) Appl. No.: 13/422,905

(22) Filed: Mar. 16, 2012

(51) Int. Cl. H01L 31/042; H01R 43/00; H01L 23/12; H01L 31/02

(52) U.S. Cl. 136/244; 136/252; 29/825; 248/309.1; 248/220.21; 248/226.11; 248/224.8

(57) ABSTRACT

A photovoltaic module mounting system includes a spacer pad, an adhesive material on a first side of the spacer pad, and a first engaging element on a second side of the spacer pad. The spacer pad is configured to be adhered to a photovoltaic module by the adhesive on the first side, and the first engaging element is configured to engage with a second engaging element of a support structure.

### FIELD OF THE INVENTION

Embodiments of the invention relate to a photovoltaic module mounting system, and more particularly to systems and methods for mounting photovoltaic modules to a support structure using adhesive mounting pads attachable to the modules and having first engaging elements.

A photovoltaic module is a device that converts sunlight energy into electricity. Photovoltaic modules include a plurality of photovoltaic cells, also known as solar cells, for example, crystalline silicon cells or thin-film cells. The photovoltaic cells are typically formed between front and back support panels of the photovoltaic module. In thin-film photovoltaic modules, the photovoltaic cell can include sequential layers of various materials formed between the front panel and the back panel. The material layers can include, for example, a transparent conducting oxide (TCO) layer, an active material layer, and a back contact layer. The active material layer may include at least a semiconductor window layer and a semiconductor absorber layer, each formed of one or more layers of semiconductor material. As one example, a window layer can be formed of cadmium sulfide (CdS), and an absorber layer can be formed of cadmium telluride (CdTe) or copper indium gallium diselenide (CIGS), or other suitable semiconductor light absorbing material.

The front and back panels provide structural integrity and protect the solar cells from environmental hazards. The front and back panels are made of a transparent material, for example, glass. The transparent front panel allows light to pass through to the active material layer. As light strikes the active material, the active material generates electricity.

The installation of photovoltaic modules can be a cumbersome process. In conventional installation systems, brackets are often used to fasten peripheral edges of the photovoltaic modules onto support structures. Since photovoltaic modules are held at their edges, they must include robust front and back panels to support the weight of the photovoltaic modules and to endure any environmental stresses, such as wind, to which they may be subjected. Accordingly, tempered glass is often used as front and back panels. In some systems, frames are formed around each photovoltaic module to provide additional support and to aid in installation. Framed photovoltaic modules are also connected to a support structure by brackets at their edges.

The strong front and back panels and/or frames required for conventional installation systems increase costs of the photovoltaic modules. Further, the added weight makes shipment and installation more difficult and time consuming. Accordingly, there is a need for a photovoltaic module mounting system that provides improved support for photovoltaic modules, enables the use of less robust front and back panels, which can be lighter and/or less rigid, and increases the speed of installation.

### BRIEF DESCRIPTION OF THE DRAWINGS

FIG. 1 illustrates a top view of an adhesive mounting pad with a male engaging element;

FIG. 2 illustrates a side view of an adhesive mounting pad with a male engaging element;

FIG. 3 illustrates a side view of a photovoltaic module with an adhesive mounting pad adhered thereto, and a support rail with a female engaging element that is flush with a surface of the rail;

FIG. 4 illustrates a side view of a photovoltaic module with an adhesive mounting pad having a male engaging element that is connected to a female engaging element of a support rail;

FIG. 5 illustrates a side view of a photovoltaic module with an adhesive mounting pad adhered thereto, and a support rail with a female engaging element that protrudes from a surface of the rail;

FIG. 6 illustrates a side view of a photovoltaic module with an adhesive mounting pad that has a female engaging element, and a support rail with a male engaging element recessed into a surface of the support rail;

FIG. 7 illustrates a side view of a photovoltaic module with an adhesive mounting pad that has a female engaging element, and a support rail with a male engaging element protruding from a surface of the support rail;

FIG. 8 illustrates a side view of a photovoltaic module with an adhesive mounting pad with an alternative male engaging element adhered thereto and a support rail;

FIGS. 9-10 illustrate a side view of a method of connecting a photovoltaic module with an adhesive mounting pad to a support rail;

FIG. 11 illustrates a side view of a photovoltaic module with an adhesive mounting pad having a female engaging element adhered thereto and a support rail with an modified male engaging element;

FIG. 12 illustrates a top down view of a photovoltaic modules with adhesive mounting pads having first engaging elements;

FIG. 13 illustrates a top down view of a support structure with second engaging elements;

FIG. 14 illustrates a top down view of photovoltaic modules connected to a support structure using adhesive mounting pads having first engaging elements;

FIG. 15 illustrates a top down view of photovoltaic modules connected to a support structure using adhesive mounting pads having first engaging elements in accordance with an embodiment described herein;

FIG. 16 illustrates a perspective view of a support rail with an installation channel;

FIGS. 17A-17B illustrate an installation of a photovoltaic module with male engaging elements on a support rail with an installation channel;

FIGS. 18A-18B illustrate an installation of a photovoltaic module with male engaging elements on a support rail with an installation channel and a graduated indentation.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes can be made to the specific embodiments discussed herein, without departing from the spirit or scope of the invention.

Described herein is a system and method for mounting photovoltaic modules to support structures using a plurality of spaced adhesive mounting pads that adhesively mount to the back panel of a module with each having a first engaging element for engaging with a respective second engaging element provided on a support structure. The adhesive mounting pads support the photovoltaic modules at a plurality of points on the back panel, and also provide a quick installation method. Since the modules are supported at a plurality of points across the back panel, this system enables the use of less robust, e.g., thinner, front and back panels. The system also obviates the need for stronger supports or frames typically required to support photovoltaic modules. The system of the present application may be used with photovoltaic modules having non-tempered cover glass and thin substrate glass panels, and is applicable to any application requiring the mounting of framed or unframed modules to a support structure.

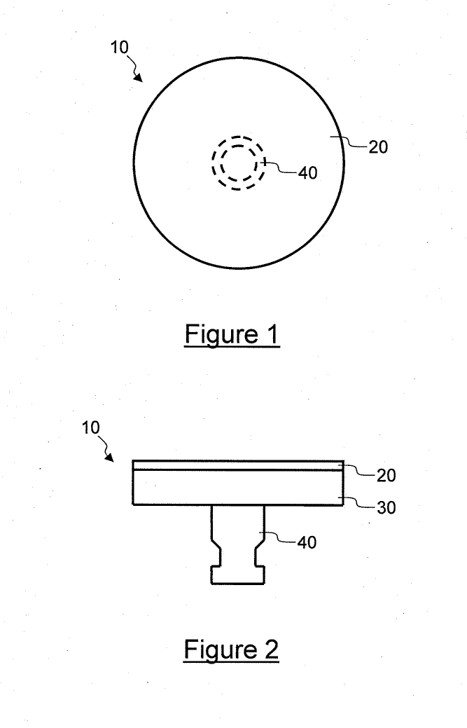

FIGS. 1 and 2 respectively illustrate a top view and a side view of an adhesive mounting pad 10 having a first engaging element 40 in accordance with an embodiment described herein. The adhesive mounting pad 10 includes an adhesive 20, which may be formed as a layer, for adhering the mounting pad 10 to a back panel of a photovoltaic module, a spacer pad 30, and a first engaging element 40 formed as a male engaging element.

The adhesive 20 can be any adhesive material suitable for adhering the adhesive mounting pad 10 to a photovoltaic module, for example, a silicone adhesive or a foam double sided adhesive. The adhesive 20 may be formed as a layer on spacer pad 30.

The spacer pad 30 is shown in FIGS. 1 and 2 as a circular pad, but can be of any other shape. For example, the spacer pad 30 can be square, rectangular, or any other polygonal shape. Likewise, adhesive 20, shown in the figures as being circular, can be of any shape. Further, the spacer pad 30 and adhesive 20 can be of different sizes, with larger diameter spacer pads 30 and adhesives 20 supporting larger surfaces of the photovoltaic module, as desired. As an example, the spacer pad 30 and adhesive 20 can be round and between two and eight inches in diameter. Different thicknesses of the spacer pad 30 can also be used to provide a larger or smaller gap between the photovoltaic module and the supporting structure, as described below. As an example, the spacer pad 30 can be between one quarter inch and two inches thick. In one embodiment, the spacer pad is round and has a diameter of about four inches and a thickness of about one inch. The spacer pad 30 can be constructed of a material that is not electrically conductive, such as a plastic or rubber material, to provide electrical isolation between the photovoltaic module and the support structure.

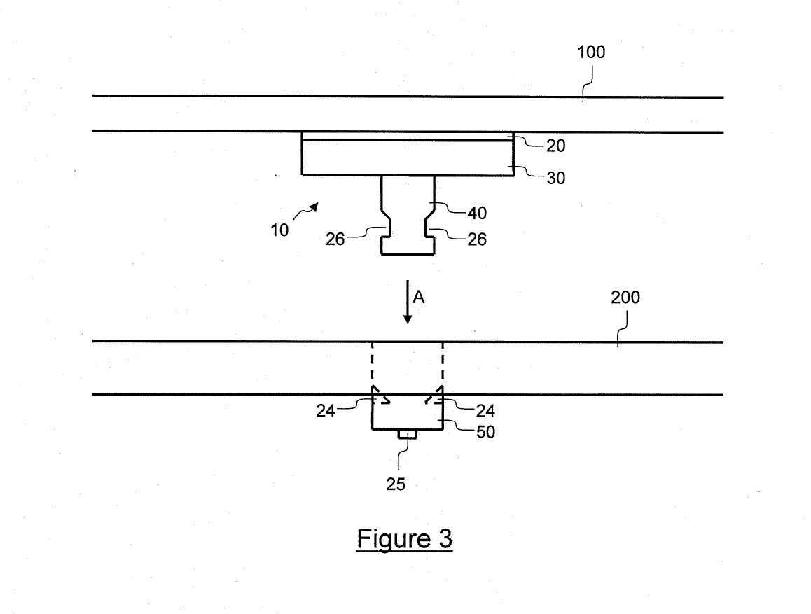

As shown in FIG. 3, the first engaging element 40, shown as a male engaging element, connects with a complementary second engaging element 50, shown as a complementary female engaging element provided at a support structure, such as a plurality of support rails 200. Any suitable connection mechanism providing first and second engaging elements which provide a secure connection between two elements can be utilized, including quick connect mechanisms such as snap connectors, and releasable quick connect mechanisms.

A plurality of adhesive mounting pads 10 can be mounted to a back panel of a plurality of photovoltaic modules 100 either during manufacture of the photovoltaic module, or after manufacture, but prior to module installation in the field. Once the mounting pads 10 are mounted on the back side of a module 100, the photovoltaic module is then connected to a support structure, such as rail 200, by engaging each first engaging element 40 with a complementary engaging element 50 provided at the support structure.

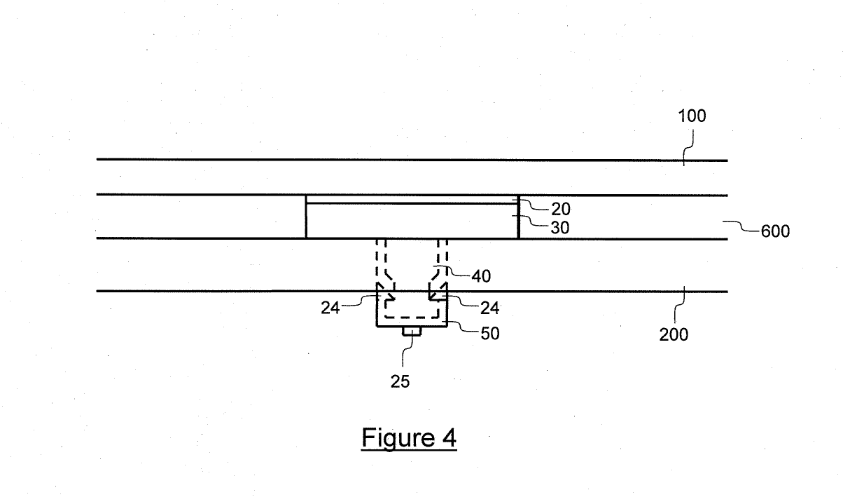

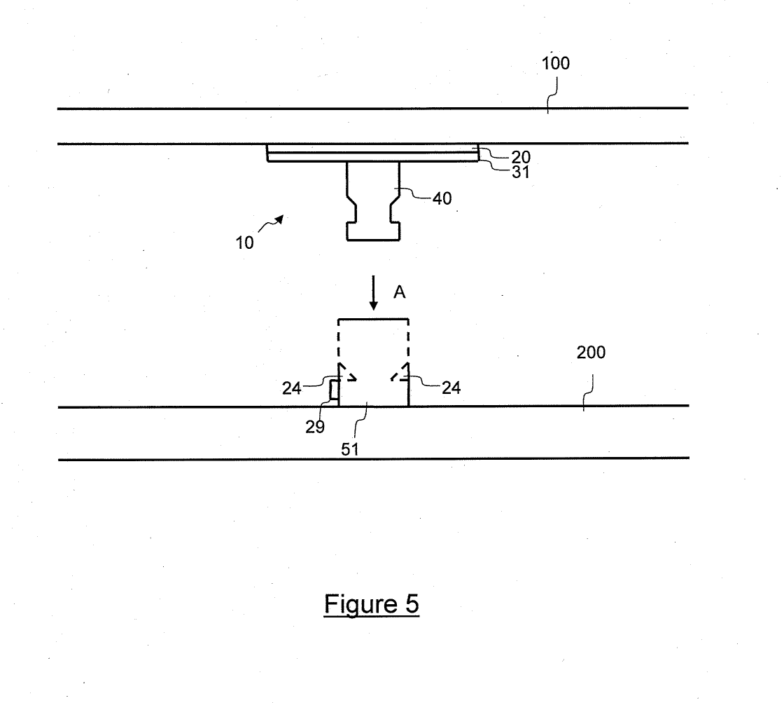

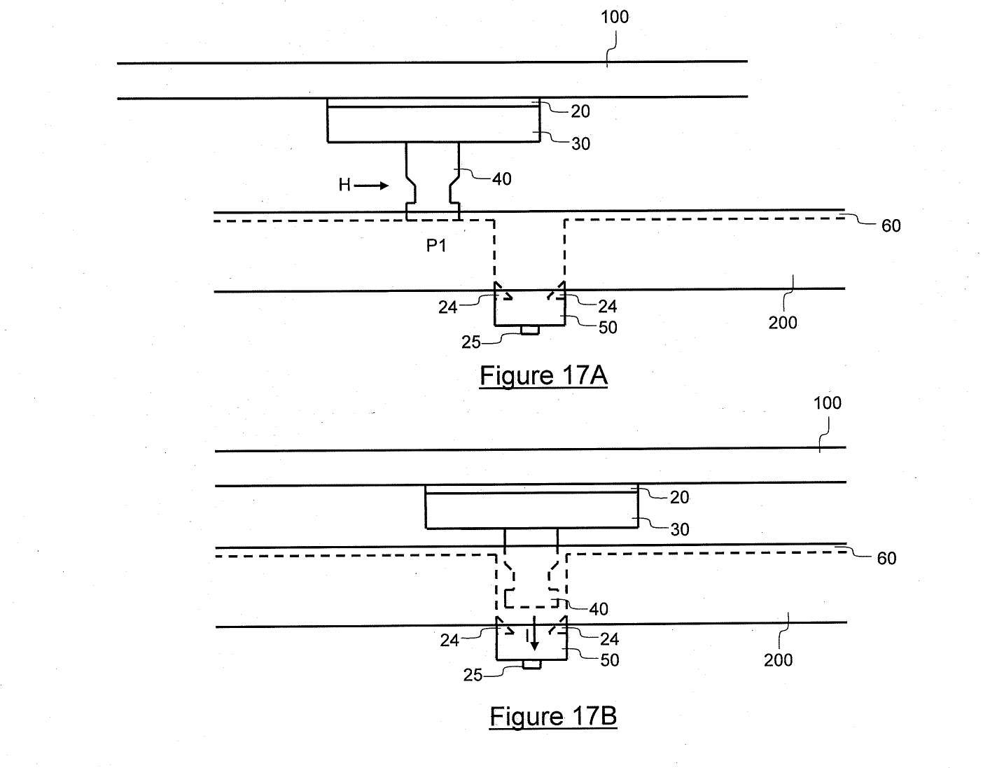

The support rails 200 can be part of a support structure that supports a photovoltaic array above a surface, for example, above ground or above a structure such as a roof of a building. The support rails 200 have the complementary second engaging elements 50 formed as a female engaging element having retractable spring loaded retainers 24. The second engaging elements 50 can be attached to the support rails, for example, by welding, by an adhesive or by using fasteners such as screws or bolts, or can be constructed as an integral part of the support rail 200, for example, as a recess formed in the rail structure. The second engaging element 50 can be flush with a surface of the support rails 200 as illustrated in FIGS. 3-4, can be configured to protrude from a surface of the support rails 200 as illustrated in FIG. 5, or can be below an upper surface of the support rails 200 as illustrated in FIGS. 17A and 17B.

Each first engaging element 40 on a module 100 connects with a respective second engaging element 50 on a support rail 200 and, when the two engaging elements are connected, the module 100 is secured to the support structure, e.g., support rail 200. On the second engaging element 50 shown in FIG. 3, retractable spring-loaded retainers 24 line up with indentations 26 in the sides of the first engaging element 40 and hold the first engaging element 40 in place when the first engaging element 40 is pressed into and connected with the second engaging element 50. While shown in FIG. 3 with two retainers 24, any number of retainers 24 can be used, including one retainer 24. The first engaging element 40 and second engaging element 50 can each be tubular in shape, with one or more retainers 24 arranged in a circle around an inside circumference of the second engaging element 50, and the indentations 26 arranged continuously around a circumference of the first engaging element 40 as a groove. The second engaging element 50 shown in FIG. 3 also includes a quick release mechanism 25 that, when pressed, causes the first engaging element 40 to be released by retracting the spring loaded retainers 24 into the body of the second engaging element 50.

FIG. 4 illustrates the photovoltaic module 100 connected to the support rail 200. When the first engaging element 40 and the second engaging element 50 are connected, the spacer pad 30 creates a space 600 between the underside of photovoltaic module 100 and the support rail 200. The spacer pad 30 supports the weight of the photovoltaic module 100. As noted earlier, the spacer pad 30 can have different thicknesses to provide a different space 600 between the modules 100 and the rail 200. When connected, as in FIG. 4, the first engaging element 40 is securely held in place by the retainers 24 of the second engaging element 50. The photovoltaic module 100 can be disconnected from the support rail 200 by pressing the quick release button 25.

The configuration of the first engaging element 40 as a male engaging element, and the complementary second engaging element 50 as a female engaging element provided flush with a rail 200 in FIGS. 2-4 is merely one example configuration of a connection mechanism, and it should be understood that other configurations can be used. For example, FIG. 5 illustrates an embodiment with a second engaging element 51 that is a female engaging element protruding from a surface of the support rail 200. In this embodiment, a quick release button 29 is located on the side of the second engaging element 51. The second engaging element 51 can be pressed into the first engaging element 40 so that they are connected to one another in the same manner as described above with reference to FIGS. 3 and 4.

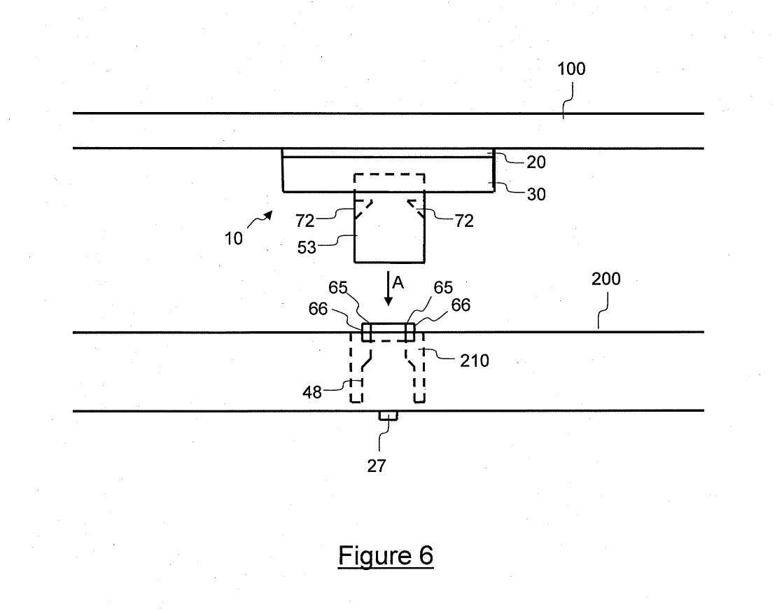

In another embodiment, illustrated in FIG. 6, a first engaging element 53 with static retainers 72 is located on the adhesive mounting pad 10. A second engaging element 48 is a male engaging element that is located in a recess 210 of the support rail 200. The first engaging element 53 is connected to the second engaging element 48 by pressing it into the second engaging element 48 in the direction indicated by arrow A. In the FIG. 6 embodiment, a quick release button 27 is located on a back side of the support rail 200, and causes spring loaded retainer tabs 66 of the second engaging element 48 to compress to the width shown by lines 65 so that it can disengage from the static retainers 72. A plurality of spring loaded retainer tabs 66 can be formed around the circumference of the second engaging element 48.

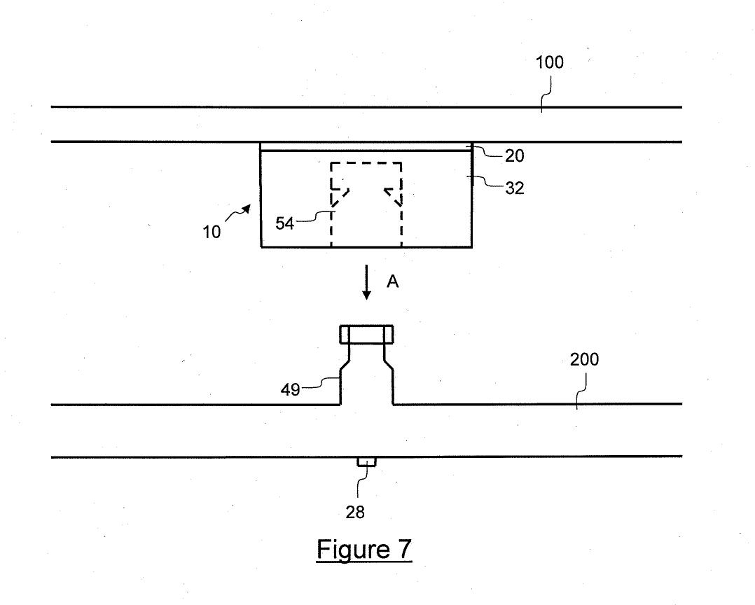

In yet another embodiment, illustrated in FIG. 7, a first engaging element 54 is a female engaging element located on adhesive mounting pad 10, and a second engaging element 49 is a male engaging element that protrudes from a support rail 200. In this embodiment, material of the spacer pad 32 is formed around the first engaging element 54, so that portions of the material will sit flush with the support rail 200 when the first engaging element 54 is pressed into and connected with the second engaging element 49. When connected, the height of the spacer pad 32 defines a space between the support rail 200 and the photovoltaic module 100. As in FIG. 6, a quick release button 28 is located on a back side of the support rail 200. In this embodiment, the space between the back side of module 100 and rail 200 is determined by the thickness of spacer pad 32.

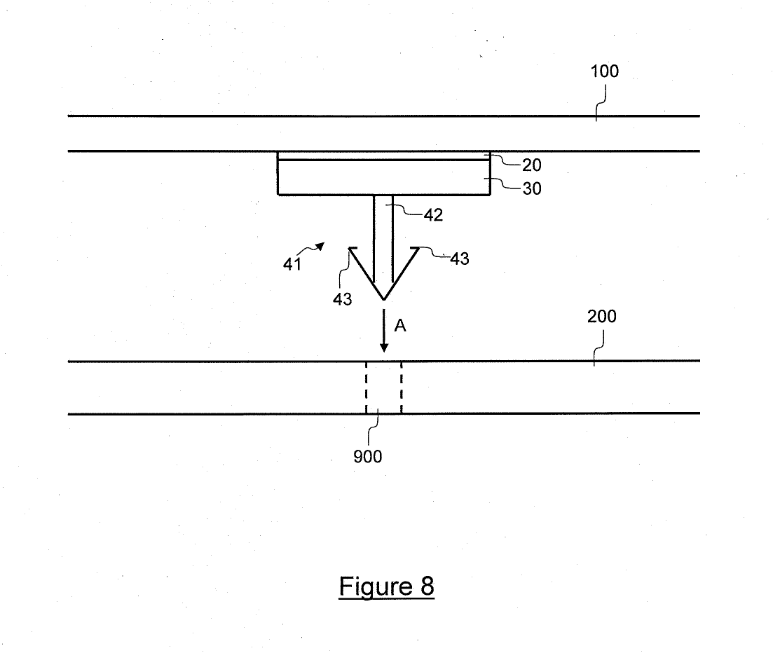

FIG. 8 illustrates a side view of a photovoltaic module with an adhesive mounting pad that has a modified first engaging element 41 that connects to a female engaging element formed as a hole 900 and surrounding structure of a rail 200. The modified first engaging element 41 includes a center shaft 42 and two wings 43, which are made out of a flexible material, such as plastic or a metal. The modified first engaging element 41 is connected by moving the photovoltaic module 100 in the direction indicated by arrow A so that the modified first engaging element 41 passes through the hole 900 in the support rail. In this embodiment, the second engaging element is the hole 900 and surrounding lower surface of rail 200.

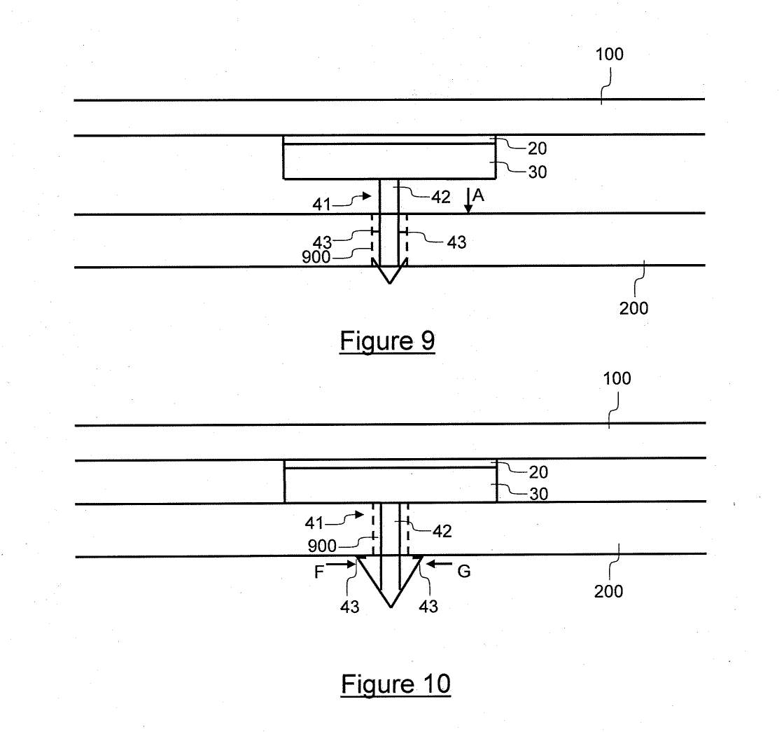

FIG. 9 shows an adhered mounting pad 10 with a modified first engaging element 41 in the process of being pressed into and connected to support rail 200. The flexible wings 43 bend inwards as they pass through the hole 900 with the application of sufficient pressure. FIG. 10 shows connection of module 100 to rail 200 after the modified first engaging element 41 has passed through the hole 900. As illustrated, the flexible wings 43 are returned to their original position and grip the back surface of rail 200 surrounding hole 900. Since the flexible wings 43 have now expanded outwards, they prevent the movement of the modified first engaging element 41 back out of the hole 900, and thus the photovoltaic module 100 is securely connected to the support rail 200. To release the photovoltaic module 100, the tops of the flexible wings 43 can be pushed inward, in the direction shown by arrows F and G in FIG. 10, so that the modified first engaging element 41 can pass back through the hole 900, releasing the connection of module 100 to rail 200.

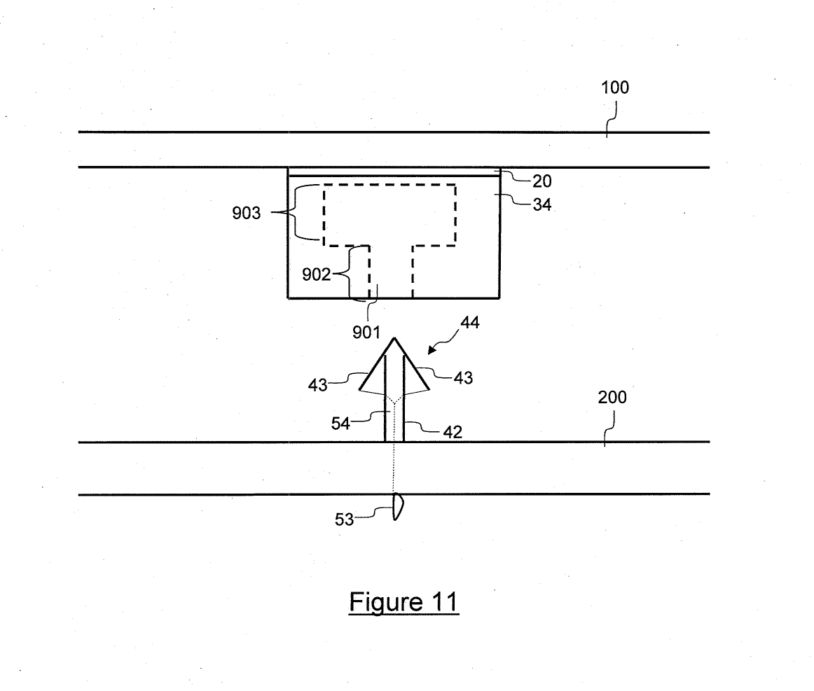

In another embodiment shown in FIG. 11, the second engaging element 44 is formed as a center shaft 42 with flexible wings 43 located on the support rails 200 while the first engaging element 57 is formed as a hole 901 provided in a spacer pad 34. A connection is made by pressing the first engaging element 57 into the second engaging element 44 and thus inserting the center shaft 42 and flexible wings 43 into the hole 901, which includes a tunnel portion 902 and an opening 903 having a wider diameter than tunnel portion 902. The connection is held by the flexible wings 43, which expand once they have been inserted past the tunnel portion 902 and into the opening 903. In the FIG. 11 embodiment, the quick release mechanism is formed as a tab 53 which is connected by connector 54, which may be a string or wire material. When the tab 53 is pulled, the flexible wings 43 are pulled and flex inward toward the center shaft 42. Once the flexible wings 43 have been flexed inward toward the center shaft 42, the second engaging element 44 can be pulled out through the tunnel portion 902, releasing the connection.

The embodiments of the first engaging element and second engaging element illustrated in FIGS. 1-11 provide specific examples of connection mechanisms for connecting a module 100 to support structures such as support rails 200, but it should be understood that variations of these connection mechanisms, and other connection mechanisms, are within the spirit and scope of the invention. Any connection mechanism can be used whereby a first engaging element of the adhesive mounting pad 10 is connected to a second engaging element associated with rail 200. This includes quick connect mechanisms, mechanisms with a quick release property, or any other secure semi-permanent or permanent connection mechanism.

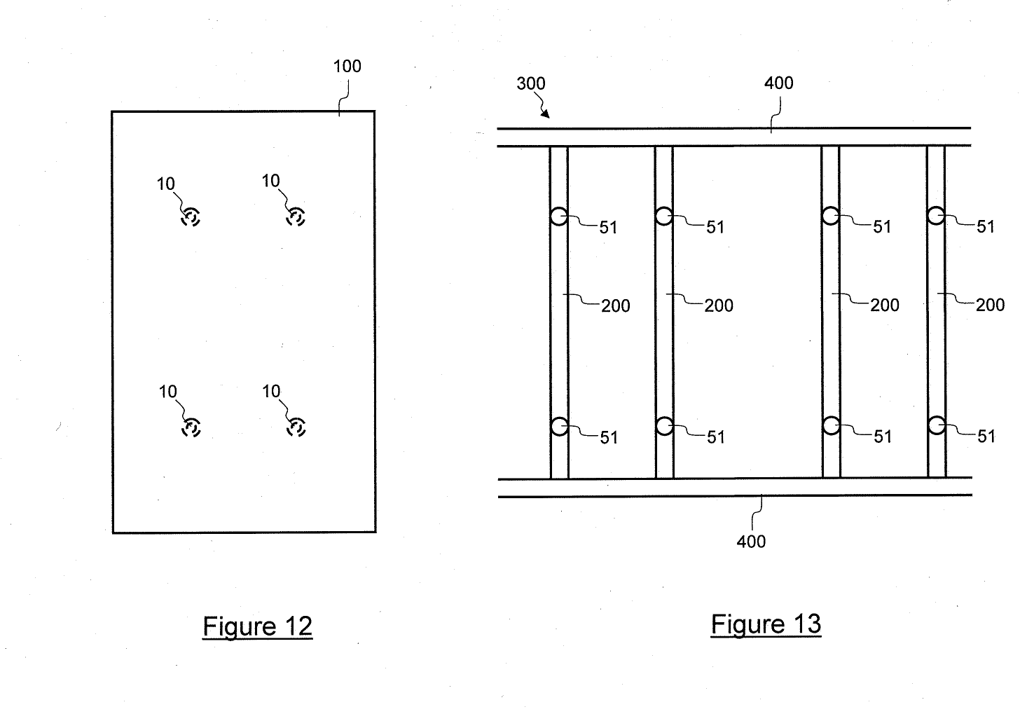

FIG. 12 illustrates a top down view of a photovoltaic module 100 with attached adhesive mounting pads 10. Multiple adhesive mounting pads 10 are adhered to the back side module 100, so as to provide multiple points of support. FIG. 12 shows four adhesive mounting pads 10 on a photovoltaic module 100, but more or less can be used, providing more or less structural support for the photovoltaic module 100.

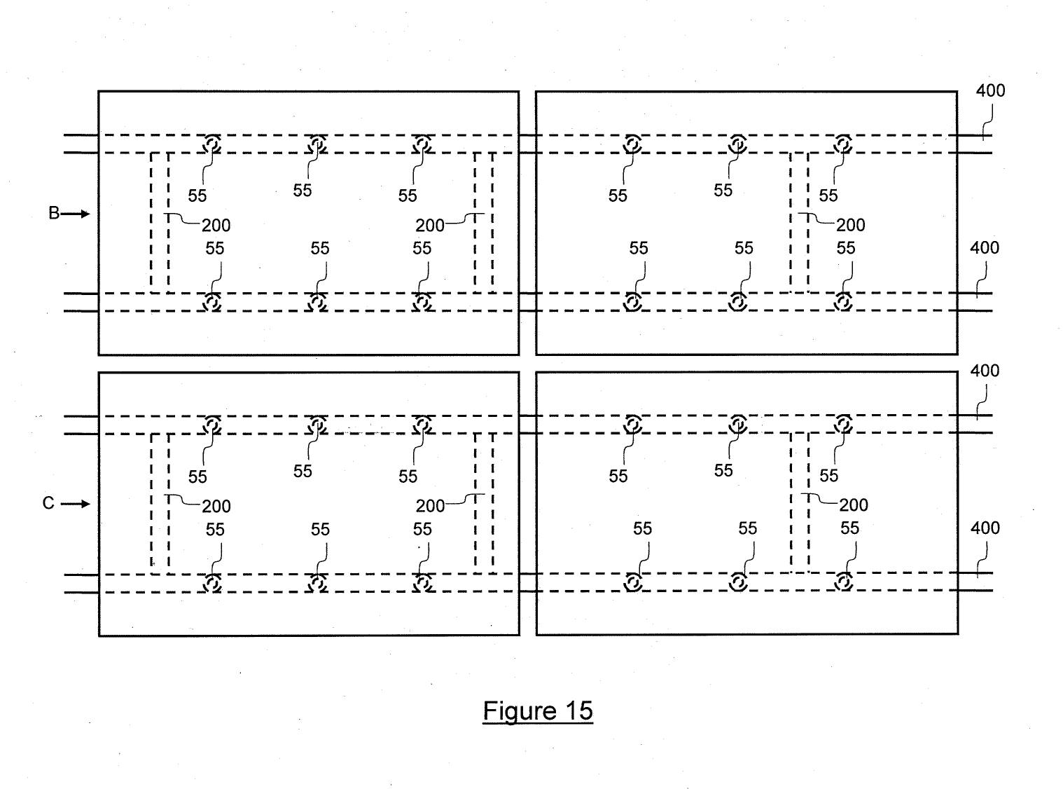

FIG. 13 illustrates a top down view of a support structure 300. The support structure 300 includes a plurality of cross support rails 200 onto which photovoltaic modules 100 can be mounted. The support structure 300 can include parallel support beams 400 that are connected by the cross support rails 200. In the FIG. 13 embodiment, each cross support rail 200 includes two second engaging elements 51. Alternatively, the second engaging elements 51 could be located on the parallel beams 400 as shown in FIG. 15.

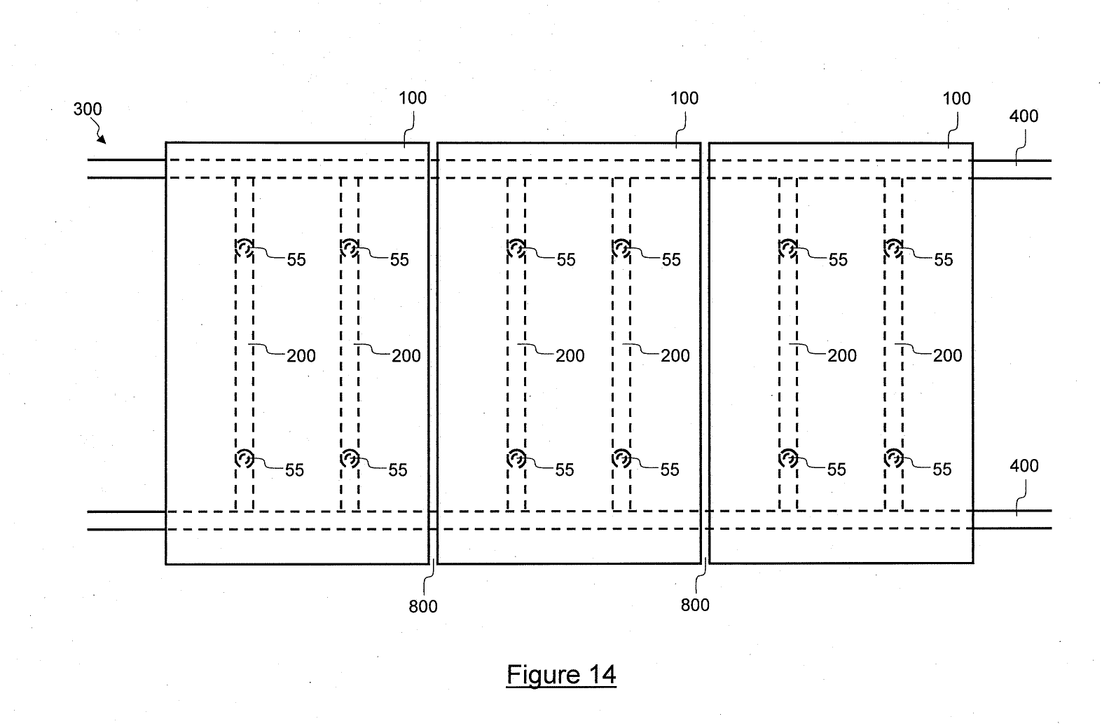

FIG. 14 illustrates a top down view of three photovoltaic modules 100 connected to support structure 300. Any number of photovoltaic modules 100 can be aligned in a row, and a plurality of adjacent rows of mounted photovoltaic modules 100 can form a photovoltaic array. First engaging elements of the adhered mounting pads 10 are connected to the second engaging elements of the support structure 300 to form connected elements 55. In the FIG. 14 embodiment, each photovoltaic module 100 is connected to cross support rails 200 at four points by connected elements 55. Additional connected elements 55 can be used to provide additional support for the photovoltaic modules 100. While shown here with a space 800 between the photovoltaic modules 100, the modules could also be arranged directly adjacent one another, without a space 800 between them.

The photovoltaic modules 100 can be connected to the support structure 300 in any orientation. For example, FIG. 15 illustrates an embodiment with photovoltaic modules 100 connected lengthwise (with the shorter ends of the photovoltaic modules 100 adjacent one another). In FIG. 15, the connected elements 55, which include the second engaging element, are attached to the parallel support beams 400, instead of the cross support rails 200, as shown in FIG. 14. FIG. 15 shows two parallel rows B and C of photovoltaic modules 100.

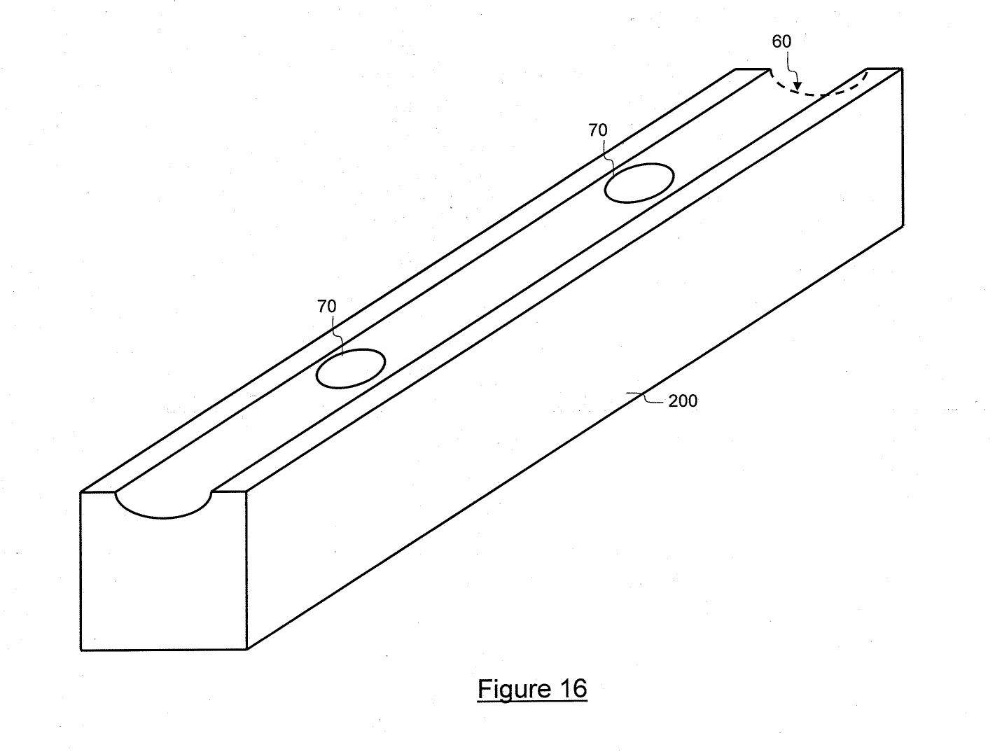

The rails 200 or beams 400 of the support structure 300 can include installation channels, or grooves, which assist in installation by guiding first engaging elements provided on a photovoltaic module into engagement with respective second engaging elements provided at the rails 200 or beams 400. FIG. 16 illustrates a perspective view of a support rail 200 with an installation channel 60 that runs the length of the support rail 200. Installation channel 60 can run the full length of the support rail 200, as shown in FIG. 16, or can be included only close to and at location 70 of the second engaging elements. The second engaging elements at location 70 are shown in FIG. 16 as holes, but could also be male or female engaging elements as shown in FIGS. 1-11. The installation channel 60 allows the first engaging elements located on the back side of a photovoltaic module to be placed into the channel 60 on a nearby point on a rail, and to slide along the length of a rail until they reach the location 70 where a connection can be made between the first and second engaging elements. The installation channels 60 make it easier to align the module 100 with the connection locations on rail 200.

FIGS. 17A-17B illustrate a side view of a photovoltaic module 100 with the quick connect structure shown in FIG. 3 being connected to a support rail 200 having an installation channel 60. In FIG. 17A, the first engaging element 40 is positioned at point P1, which is near the second engaging element 50. The walls of the installation channel 60 restrict movement in the lateral direction, and hold the first engaging element 40 on the support rail 200 as it moves in direction H. To connect the photovoltaic module 100 with the support rail 200, the photovoltaic module 100, including the first engaging element 40, is slid across the support rail 200 in direction H, until the first engaging element 40 drops into, and can be pressed into and connected with, the second engaging element 50 (shown in FIG. 17B). This installation method may be utilized with any of the embodiments described above.

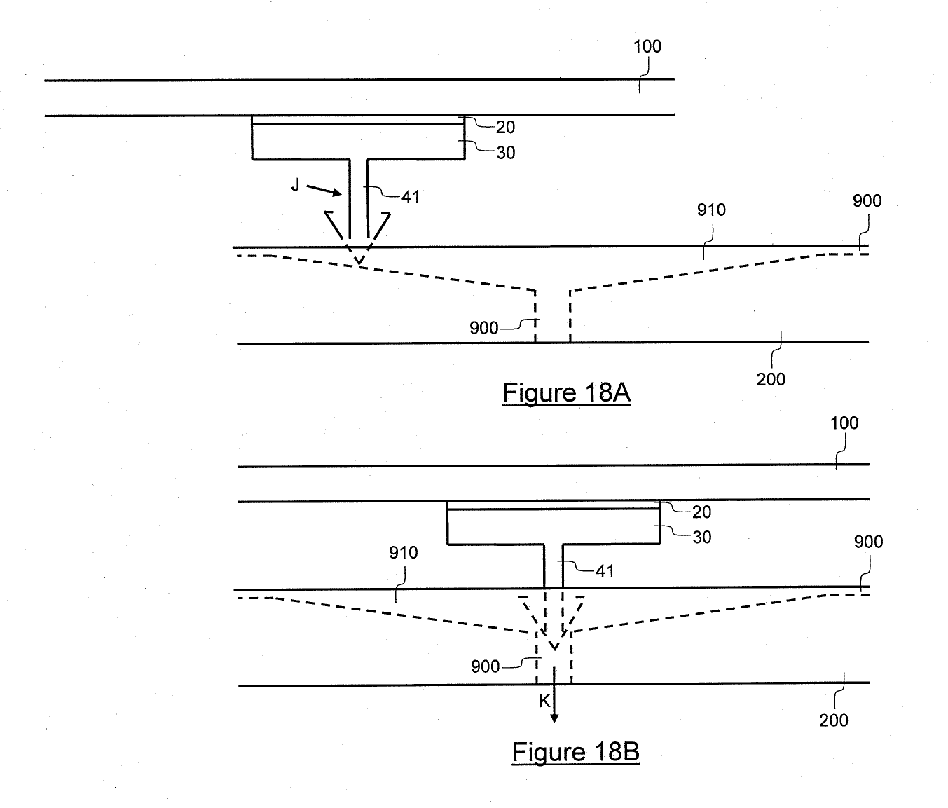

Additional guides can be used, as well. For example, a graduated indentation 910, or valley, may be formed in the rails 200 or beams 400 in areas that are near a connection point location 70. The graduated indentation 910 may be graduated in either a longitudinal or lateral direction of the rail, or both, and can be used to guide the first connection elements on the module to the second connection elements at rails 200 or beams 400. An exemplary graduated indentation 910 is illustrated in FIGS. 18A-18B. In FIGS. 18A-18B, the graduated indentation 910 is formed at locations near hole 900, which is the second engaging element. The graduated indentation 910 may be formed at multiple respective points near holes 900 along the support rail 200, and may be utilized in conjunction with an installation channel 60 formed between respective graduated indentations 910, as shown in FIGS. 18A-18B. When a first engaging element 41 is placed in the graduated indentation 910, it moves in direction J by sliding, and assisted by gravity, toward the hole 900. When it reaches the hole 900, as in FIG. 18B, it can be pressed in direction K to form a secure connection of module 100 and rail 200. While shown here in a connection embodiment using the embodiment shown in FIG. 8, the graduated indentation 910 may be utilized with any first engaging element of the embodiments described herein.

While various embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

what is claimed as new and desired to be protected by Letters Patent of the United States is:

1. A photovoltaic module mounting system comprising:
a connection structure including a spacer pad with a first side and a second side, the first side having an adhesive material applied thereto for fastening the spacer pad to a photovoltaic module, and the second side having a first engaging element configured to engage a second engaging element provided at a support structure.

2. The photovoltaic module mounting system of claim 1, further comprising:
a photovoltaic module adhered to the spacer pad by the adhesive material.

3. The photovoltaic module mounting system of claim 2, further comprising:
a plurality of the connection structures connected by a respective adhesive material to the photovoltaic module.

4. The photovoltaic module mounting system of claim 3, wherein the support structure comprises a plurality of rail or beam structures each containing a plurality of second engaging elements connected to respective first engaging elements of the plurality of connection structures.

5. The photovoltaic module mounting system of claim 4, wherein the plurality of rail or beam structures each has an installation channel along a longitudinal axis, wherein the first engaging elements slidingly engage with a respective installation channel.

6. The photovoltaic module mounting system of claim 4, wherein the plurality of rail or beam structures each has a respective graduated indentation at a respective second engaging element.

7. The photovoltaic module mounting system of claim 1, wherein the spacer pad is formed of a non-conductive material.

8. The photovoltaic module mounting system of claim 1, wherein the spacer pad is formed of plastic.

9. The photovoltaic module mounting system of claim 1, wherein the spacer pad is formed of rubber.

10. The photovoltaic module mounting system of claim 2, wherein the photovoltaic module comprises a non-tempered glass back panel, and the spacer pad is adhered to the back panel.

11. The photovoltaic module mounting system of claim 1, wherein the first engaging element is a male engaging element, and the second engaging element is a female engaging element.

12. The photovoltaic module mounting system of claim 1, wherein the second engaging element includes a mechanism for releasing engagement of the first and second engaging elements.

13. The photovoltaic module mounting system of claim 12, wherein the mechanism for releasing engagement retracts at least one retainer.

14. The photovoltaic module mounting system of claim 1, wherein the first engaging element is a female engaging element, and the second engaging element is a male engaging element.

15. The photovoltaic module mounting system of claim 14, wherein the female engaging element is located at least partially recessed within a surface of the spacer pad.

16. The photovoltaic module mounting system of claim 14, wherein the male engaging element is located at least partially recessed in the support structure.

17. The photovoltaic module mounting system of claim 1, wherein the first engaging element has indentations that align with retainers of the second engaging element when the first engaging element is connected with the second engaging element.

18. The photovoltaic module mounting system of claim 1, wherein the first engaging element comprises a center shaft having flexible wings outwardly extending therefrom.

19. The photovoltaic module mounting system of claim 18, wherein the second engaging element is a hole and surrounding portion of a rail or beam.

20. The photovoltaic module mounting system of claim 1, wherein the first engaging element is a hole in the spacer pad having a tunnel portion and an opening portion that is larger in diameter than the tunnel portion, and the second engaging element comprises a center shaft having flexible wings outwardly extending therefrom.

21. The photovoltaic module mounting system of claim 1, wherein the spacer pad is between one quarter inch and two inches thick.

22. The photovoltaic module mounting system of claim 1, wherein the spacer pad is between two inches and eight inches in diameter.

23. The photovoltaic module mounting system of claim 1, wherein the spacer pad is a polygon shape with at least one side that is between two inches and eight inches long.

24. The photovoltaic module mounting system of claim 1, wherein the spacer pad is about one inch thick and about four inches in diameter.

25. The photovoltaic module mounting system of claim 1, wherein a thickness of the spacer pad defines a space between the photovoltaic module and the mounting rail when the first engaging element is connected to the second engaging element.

26. The photovoltaic module mounting system of claim 1, wherein a length of the first engaging element defines a space between the photovoltaic module and the mounting rail when the first engaging element is connected to the second engaging element.

27. A method of mounting a photovoltaic module, comprising:
adhering a plurality of connection structures to a back side of the photovoltaic module, the connection structures each comprising a spacer pad and a first engaging element; and
connecting the first engaging elements to a plurality of respective second engaging elements on a support structure.

28. The method of mounting of claim 27, further comprising:
after the adhering, placing the first engaging elements on respective installation channels of at least two rails or beams of the support structure; and
sliding the connection structures across a portion of the at least two rails or beams to a location where the connection structures can engage with the support structure through respective first and second engaging elements.

29. The method of mounting of claim 27, further comprising:
after the adhering, placing the first engaging elements in graduated indentations at the respective second engaging elements on the at least two rails or beams; and
sliding the connection structures across a portion of the at least two rails or beams.

30. A photovoltaic module mounting system comprising:
a photovoltaic module;
a plurality of connection structures adhered to a back side of the photovoltaic module, the connection structures each comprising a spacer pad and a first engaging element configured to connect with a second engaging element.

31. The photovoltaic module mounting system of claim 30, further comprising:
a support structure connected to the respective first engaging elements of the plurality of connection structures by a plurality of second engaging elements on the support structure.

32. The photovoltaic module mounting system of claim 30, further comprising:
a plurality of photovoltaic modules, each photovoltaic module having a plurality of the connection structures connected to the support structure.
